(19) United States
(12) Patent Application Publication
(10) Pub. No.: US 2006/0134950 A1
(43) Pub. Date: Jun. 22, 2006

(54) Contact for CPU socket

(75) Inventors: Fang-Jwu Liao, Tu-Cheng (TW); Ming-Lun Szu, Chandler, AZ (US)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/311,843

(22) Filed: Dec. 19, 2005

(30) Foreign Application Priority Data
Dec. 17, 2004 (TW) 93220378

(51) Int. Cl. H05K 1/00

(52) U.S. Cl. 439/83

(57) ABSTRACT

A contact (1) for a CPU socket includes a base (10) secured in the socket and a pair of arm sections (20) extending from opposite lateral sides of the base. Each arm section comprises an upper arm (21) extending from a body section (12) of the base, a forearm (25) extending obliquely, circuitously and upwardly from a free end of the upper arm, a contact region (27) divergently away from each other at a free end of the forearm. The pair of forearms defines a first space (251) therebetween, and the pair of contact regions defines a second space (271) therebetween. The first space communicates with the second space at a narrow channel (272) defined between the forearms. A pin (2) of a CPU is adapted to engage with the contact regions and establish electrical connection therebetween.

### BACKGROUND OF THE INVENTION

1. Field of the Invention

The present invention relates to a contact for an electrical connector, and particularly to a contact for a CPU (Central Processing Unit) socket.

2. Description of the Prior Art

U.S. Pat. No. 4,498,725 discloses a conventional terminal 3′ for a CPU socket, as is shown in FIG. 4. The terminal 3′ comprises a base 31′, a soldering tail 34′ depending from the base 31′, and a pair of arms 32′ extending perpendicular outwardly from two opposite lateral sides of the base 31′. The arm comprises a retaining arm 321′ received in a housing of the CPU socket and a forearm 322′ extending obliquely and downwardly from a free end of the retaining arm 321′. A pair of contact regions 33′ is extended downwardly from a corresponding free ends of the forearms 322′. A distance between the forearms 322′ is greater than that between the contact regions 33′.

A pin of a CPU (not shown) is resiliently clamped between the forearms 322′ and contacted with the contact regions 33′ for establishing an electrical connection therebetween. As the forearms 322′ are cantilevers, their resilience is relatively small. The forearms 322′ cannot apply sufficient mating force against the pin to ensure reliable engagement between the pin and the contact regions 33′. Thus when the terminal 3′ or the pin is subjected to vibration or shock, the pin is sometimes dislodged.

Thus, there is a need to provide a contact for CPU socket that overcomes the above-mentioned problems.

### SUMMARY OF THE INVENTION

Accordingly, an object of the present invention is to provide a contact for a CPU socket providing improved mating force against a pin of a CPU.

To fulfill the above-mentioned object, a contact for a CPU socket in accordance with a preferred embodiment of the present invention comprises a base and a pair of arm sections. The base has a body section adapted to optionally abut against the housing of the socket in the corresponding passageway in which the contact is received, a head section for being secured in the CPU socket, and a soldering section for being soldered onto a printed circuit board via a solder ball. Each arm section comprises an upper arm projecting obliquely and downwardly from a lateral side of the body section and adapted to optionally abut against the housing of the socket in the corresponding passageway, a forearm extending obliquely, circuitously and upwardly from a free end of the upper arm, a contact region divergently away from each other at a free end of the forearm. A first space is defined between the forearms and a second space is defined between the contact regions, and a channel is defined between the first and second spaces to connect the first and second spaces. A width of the channel is not only narrower than that of the first space, but also narrower than that of the second space. A pin of a CPU is adapted to engage with the contact regions and establish electrical connection therebetween. Since the forearm and the upper arm are resiliently located on the contact to provide great resilience for the contact region located at a free end of the forearm, mating force exerted by the contact regions against the pin of the CPU is enhanced than the conventional contact.

Other objects, advantages and novel features of the present invention will become more apparent from the following detailed description when taken in conjunction with the accompanying drawings, in which:

### BRIEF DESCRIPTION OF THE DRAWINGS

FIG. 1 is isometric view of a contact for a CPU socket in accordance with a preferred embodiment of the present invention;

FIG. 2 is an isometric view of FIG. 1, together with an engaging pin of a CPU;

FIG. 3 is an elevational view of FIG. 1.

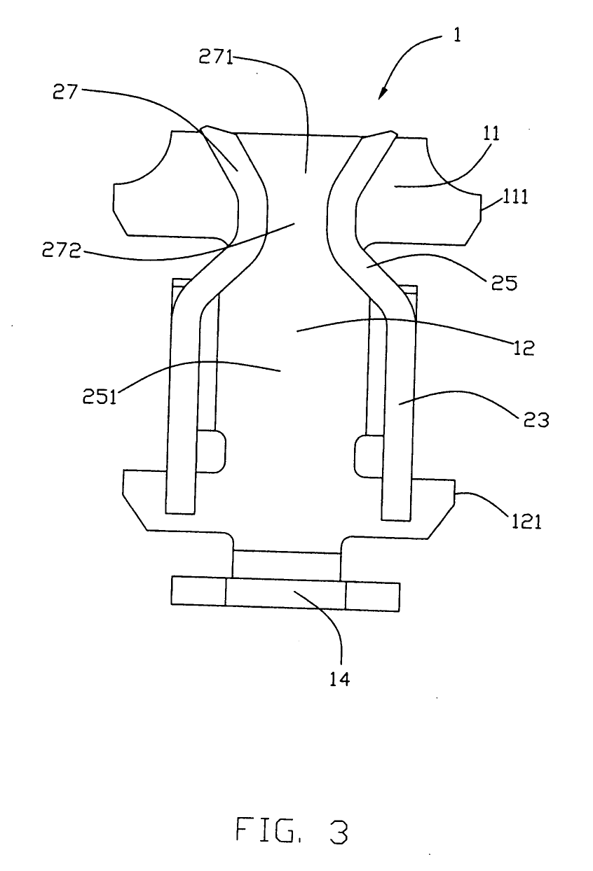

FIG. 4 is an isometric view of a conventional contact for a CPU socket.

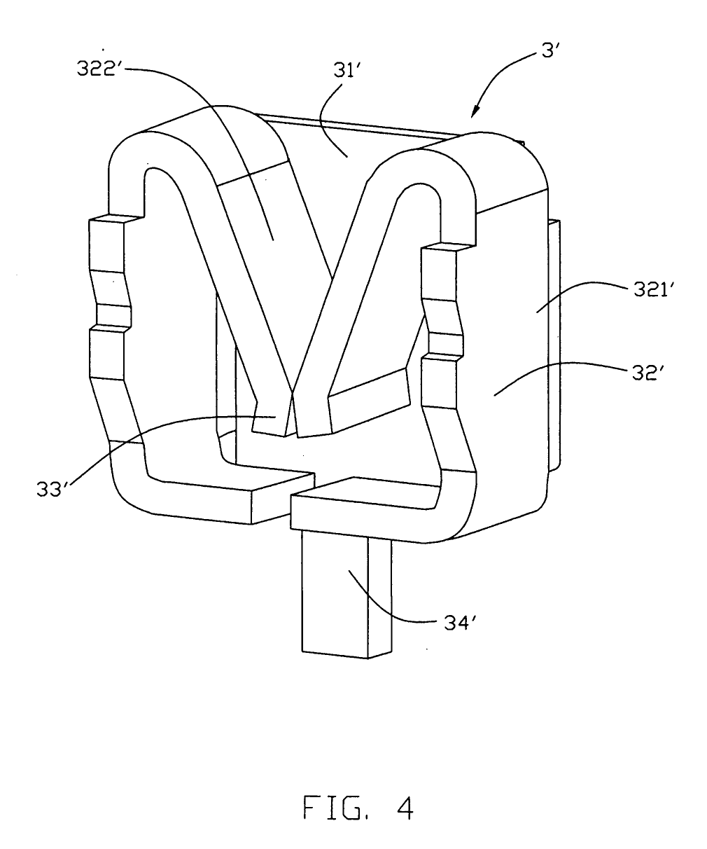

### DESCRIPTION OF PREFERRED EMBODIMENT OF THE INVENTION

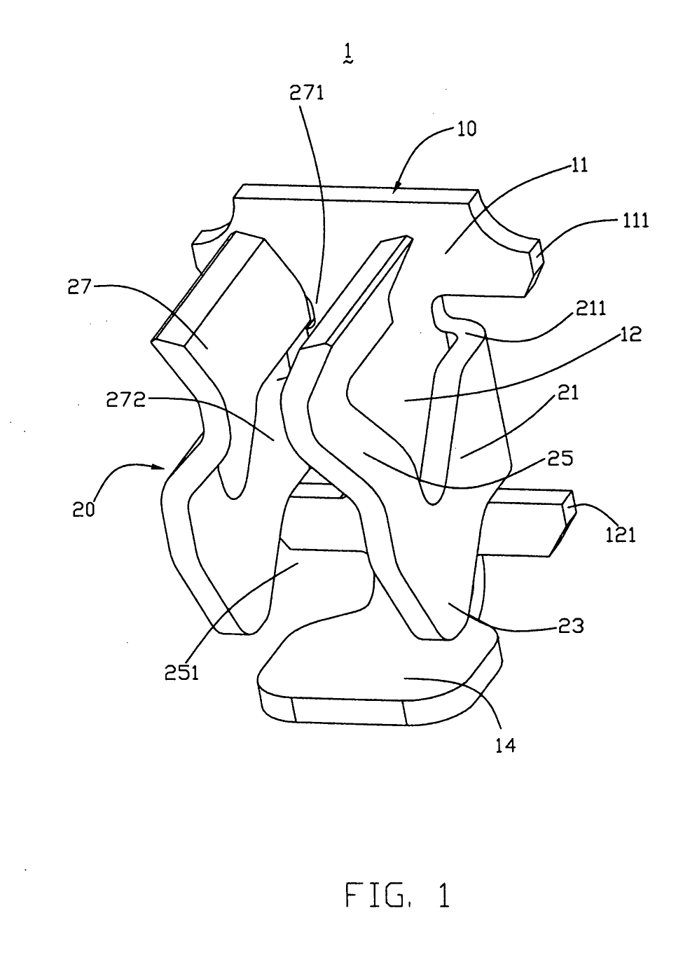

Reference will now be made to the drawings to describe the present invention in detail. FIG. 1 is an exploded, isometric view of a contact 1 for a CPU socket (not shown) in accordance with the preferred embodiment of the present invention. The contact 1 comprises a base 10 and a pair of arm sections 20 connected to the base 10.

The base 10 comprises a body section 12, a head section 11 upwardly projecting from the body section 12, and a soldering section 14 extending perpendicularly from a bottom edge of the body section 12. A pair of upper projections 111 is respectively formed at top portions of opposite lateral edges of the head section 11, and a pair of lower projections 121 is respectively formed at bottom portions of the opposite lateral edges of the body section 12, for interferingly securing the contact 1 in the CPU socket. A junction 211 is defined where each arm section 20 meets the body section 12.

Each arm section 20 comprises an upper arm 21 extending obliquely downwardly from one lateral edge of the body section 12 toward the soldering section 14, an elbow 23 at a bottom portion of the upper arm 21, a forearm 25 extending obliquely, circuitously and upwardly from a free end of the upper arm 21, a contact region 27 divergently away from each other at a free end of the forearm 25. Each forearm 25 extends from a corresponding elbow 23 toward each other in a direction whose projection in side view is essentially parallel to the body section 12. The forearms 25, elbows 23 and contact regions 27 together define a bellow first space 251. A second space 271 is defined between the contact regions 27, in communication with the first space 251 at a channel 272 connected between the first and second spaces 251, 271. A portion of the first space 251 between the elbows 23 is wider than that of the channel 272 between the forearms 25. A portion of the second space 271 between the contact regions 27 is narrower than that of the first space 251 between the elbows 23. The first space 251 and the second space 271 are respectively contained in the first and second planes to be perpendicular to each other.

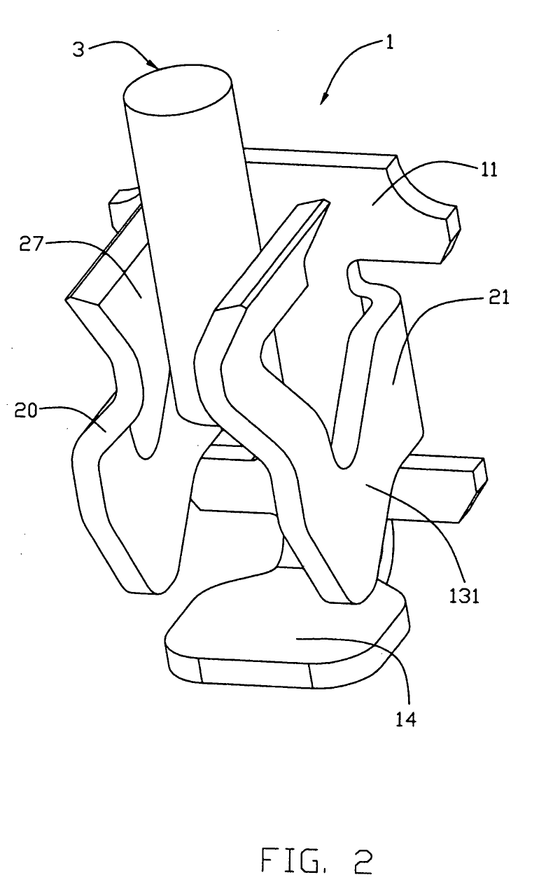

As is indicated in FIG. 2, a pin 3 of a CPU engages with the contact 1. The soldering section 14 of the contact 1 is adapted for being soldered onto a printed circuit board (not shown) by a soldering ball (not shown), for establishing an electrical connection between the pin 3 and an electrical trace of the printed circuit board. Initially, the pin 3 is guided in the second space 271 and slid in the second space 271, at the same time, the arm sections 20 are outwardly deformed, particularly about the junctions 211, thereby the pin 3 is engaged with the contact regions 27 to provide reliably electrical connection between the contact 1 and the CPU. Resilient deformation of the arm sections 20 creates mating force to ensure the pin 3 is tightly clamped between the contact regions 27.

In the present invention, the forearm 25 and the upper arm 21 are resiliently located on the contact 1 to provide great resilience for the contact region 27 located at a free end of the forearm 25, mating force exerted by the contact regions 27 against the pin 3 of the CPU is enhanced than the conventional contact.

Although the present invention has been described with reference to particular embodiments, it is not to be construed as being limited thereto. Various alterations and modifications can be made to the embodiments without in any way departing from the scope or spirit of the present invention as defined in the appended claims.

What is claimed is:

1. A contact for a CPU socket for electrically connecting a pin of a CPU with a trace of a printed circuit board, comprising:
a base defining a body section for being secured in the CPU socket, and a soldering section for being soldered onto the printed circuit board; and
a pair of arm sections extending from opposite lateral sides of the body section; wherein;
the arm sections comprises an upper arm extending obliquely downwardly from one lateral edge of the body section toward the soldering section, a forearm extending obliquely, circuitously and upwardly from a free end of the upper arm, and a contact region divergently away from each other at a free end of the forearm for facilitating guiding of the pin during insertion of the pin into the contact.

2. The contact as claimed in claim 1, wherein the forearms extend upwardly toward each other and essentially parallel to the body section.

3. The contact as claimed in claim 2, wherein the forearms define a first space therebetween and the contact regions define a second space therebetween, the first space communication with the second space at a channel defined by the forearms.

4. The contact as claimed in claim 3, wherein a portion of the second space is narrower than the first space, and greater than the channel.

5. The contact as claimed in claim 4, wherein the base respectively forms at least two projections on opposite lateral sides thereof adjacent the body section, for securing the contact in the CPU socket.

6. The contact as claimed in claim 5, wherein projections are formed above and below the boy section.

7. The contact as claimed in claim 6, wherein a head section coplanarly extends upward from an upper edge of the body section and a pair of barbs is formed on two side edges thereof.

8. A contact for use within a passageway of a housing of a connector, comprising:
a vertical body section adapted to abut against the housing in the passageway;
a set of barbs formed on two side edges of the body section for interferential engagement with the housing;
a solder section horizontally extending from a lower edge of the body section for mounting to a printed circuit board on which the connector is seated;
a head section coplanarly extending upward from an upper edge of the body section and another set of barbs formed on two side edges thereof;
a pair of upper arms respectively extending little bit downwardly form the side edges above the barbs in a parallel relation adapted to abut against the housing, the upper arms extending beyond the solder section in a horizontal direction;
a pair of forearms respectively extending obliquely, circuitously and upwardly from distal ends of the pair of upper arms in a converging manner toward each other;
a pair of contact regions respectively formed at upper tips of the pair of forearms in a parallel relation with each other.

9. A contact for use with a pin type complementary contact, comprising:
a planar body section;
a pair of upper projections and a pair of lower projections located on upper and lower portions of said body section;
a pair of arm sections extending from two side edge of the body section and between said pair of upper projections and said pair of lower projections in a vertical direction;
said pair of arm sections includes a pair of opposite forwardly extending upper arms, a pair of opposite upwardly extending forearms which extend toward each other at upper ends, and a pair of contact regions upwardly extending away from each other; wherein
a joint portion between the contact region and the corresponding forearm is essentially located around the upper portions of the body section from an elevational viewpoint.
